(19) United States
(12) Patent Application Publication
(10) Pub. No.: US 2022/0392851 A1
(43) Pub. Date: Dec. 8, 2022

(54) SEMICONDUCTOR CHIP AND MANUFACTURING METHOD THEREOF

(71) Applicant: SAMSUNG ELECTRONICS CO., LTD., Suwon-si (KR)

(72) Inventors: Hwayoung Lee, Hwaseong-si (KR); Hyunsu Sim, Cheonan-si (KR); Junho Yoon, Anyang-si (KR)

(73) Assignee: SAMSUNG ELECTRONICS CO., LTD., Suwon-si (KR)

(21) Appl. No.: 17/674,549

(22) Filed: Feb. 17, 2022

(30) Foreign Application Priority Data
Jun. 7, 2021 (KR) 10-2021-0073205

(51) Int. Cl. H01L 23/00; H01L 21/304; H01L 21/78

(52) U.S. Cl. CPC H01L 23/562; H01L 21/3043; H01L 21/78

(57) ABSTRACT

A method of manufacturing a semiconductor chip includes preparing a semiconductor substrate having an active surface on which a device layer is provided and an inactive surface opposite to the active surface, the device layer having a integrated circuit (IC) areas and a cut area provided between adjacent IC areas; forming anti-collision recesses in regions of the cut area that are adjacent to corners of the IC areas, each of the anti-collision recesses having rounded internal sidewalls, each of the rounded internal sidewalls corresponding to a respective corner of the adjacent corners; forming a modified portion in the semiconductor substrate by irradiating a cut line of the cut area with a laser; polishing the inactive surface of the semiconductor substrate, wherein cracks propagate from the modified portion in a vertical direction of the semiconductor substrate; and separating the IC areas from each other along the cracks to form semiconductor chips.

### CROSS-REFERENCE TO RELATED APPLICATION(S)

This application claims priority to Korean Patent Application No. 10-2021-0073205 filed on Jun. 7, 2021 in the Korean Intellectual Property Office, the disclosure of which is incorporated by reference herein in its entirety.

### BACKGROUND

The present disclosure relates to a semiconductor chip and a manufacturing method thereof.

Integrated circuits (ICs) are formed on an active surface of a semiconductor substrate. An inactive surface of the semiconductor substrate is polished, and the polished semiconductor substrate is cut to separate the ICs into respective semiconductor devices (or semiconductor chips). In general, the polished semiconductor substrate is mechanically cut using a sawing blade. Such mechanical cutting may cause cut surfaces of the semiconductor chips to be broken, thereby causing many defects in the semiconductor chips. Therefore, a method of cutting semiconductor substrates using a laser has been studied.

### SUMMARY

One or more example embodiments provide a method of manufacturing a semiconductor chip to suppress an occurrence of defects such as cracks in a process of cutting a semiconductor substrate into a plurality of semiconductor devices.

Further, one or more example embodiments provide a semiconductor chip that may be manufactured by a process of cutting a semiconductor substrate capable of suppressing an occurrence of defects such as cracks.

According to an aspect of an example embodiment, there is provided a method of manufacturing a semiconductor chip, the method including: preparing a semiconductor substrate having an active surface on which a device layer is provided and an inactive surface opposite to the active surface, the device layer having a plurality of integrated circuit (IC) areas and a cut area provided between adjacent IC areas of the plurality of IC areas; forming anti-collision recesses in regions of the cut area that are adjacent to corners of the plurality of IC areas, each of the anti-collision recesses having rounded internal sidewalls, each of the rounded internal sidewalls corresponding to a respective corner of the adjacent corners; forming a modified portion in the semiconductor substrate by irradiating a cut line of the cut area with a laser; polishing the inactive surface of the semiconductor substrate; and separating the plurality of IC areas from each other along the cracks that propagate from the modified portion in a vertical direction of the semiconductor substrate, to form a plurality of semiconductor chips.

According to an aspect of an example embodiment, there is provided a method of manufacturing a semiconductor chip, the method including: preparing a semiconductor substrate having an active surface on which a device layer is provided and an inactive surface positioned opposite to the active surface, the device layer having a plurality of integrated circuit (IC) areas arranged in a plurality of rows and a plurality of columns and a cut area provided between adjacent IC areas of the plurality of IC areas, each of the plurality of IC areas having a quadrangular shape; forming anti-collision recesses in regions of the cut area that are adjacent to four corners of the plurality of IC areas, each of the anti-collision recesses having inwardly curved and rounded internal sidewalls, each of the internal sidewalls corresponding to a respective corner of the four corners; forming a modified portion in the semiconductor substrate by irradiating a cut line of the cut area with a laser; polishing the inactive surface of the semiconductor substrate in a state in which the active surface is disposed in a support; and separating the plurality of IC areas from each other along cracks that propagate from the modified portion in a vertical direction of the semiconductor substrate, to form a plurality of semiconductor chips.

According to an aspect of an example embodiment, there is provided a semiconductor chip including: a semiconductor substrate having a first surface and a second surface positioned opposite to the first surface, the semiconductor substrate having a rectangular parallelepiped structure; and a device layer provided on the first surface, the device layer having an integrated circuit (IC) area and a peripheral protective area surrounding the IC area, the IC area including semiconductor devices and interconnection layers, wherein the peripheral protective area has recessed portions so that regions of the first surface of the semiconductor substrate adjacent to four corners of the IC area are exposed, and wherein each of the recessed portions of the peripheral protective area has a rounded side surface.

### BRIEF DESCRIPTION OF DRAWINGS

The above and other aspects, features, and advantages of certain example embodiments of the disclosure will be more clearly understood from the following detailed description, taken in conjunction with the accompanying drawings, in which:

FIG. 1 is a perspective view illustrating a wafer structure having a device layer;

FIG. 2A is an enlarged plan view of portion A of FIG. 1 and FIG. 2B is a side cross-sectional view taken along line I-I′ of FIG. 2A;

FIG. 3 is a perspective view illustrating a wafer structure according to an example embodiment;

FIG. 4A is an enlarged plan view of portion A of FIG. 2, FIG. 4B is a side cross-sectional view taken along line I-I′ of FIG. 4A;

FIG. 5 is a perspective view illustrating a process of attaching a protective sheet to a semiconductor substrate according to an example embodiment;

FIG. 6 is a side cross-sectional view of a wafer structure to which a protective sheet is attached, taken along line II-II′ of FIG. 5;

FIG. 7 is a perspective view illustrating a process of irradiating an inside of a semiconductor substrate with a laser according to an example embodiment;

FIG. 8 is a side cross-sectional view illustrating a semiconductor substrate irradiated with a laser according to an example embodiment;

FIG. 9 is a side cross-sectional view illustrating a process of polishing a semiconductor substrate according to an example embodiment;

FIG. 10 is a side cross-sectional view illustrating a process of cutting a semiconductor substrate into semiconductor chips according to an example embodiment;

FIGS. 11 and 12 are perspective views illustrating a semiconductor chip according to various example embodiments;

FIGS. 13A and 13B are a side cross-sectional view and a plan view illustrating a semiconductor package including a semiconductor chip according to an example embodiment; and

FIG. 14 is a side cross-sectional view illustrating a semiconductor package including a semiconductor chip according to an example embodiment.

### DETAILED DESCRIPTION

Hereinafter, example embodiments will be described with reference to the accompanying drawings.

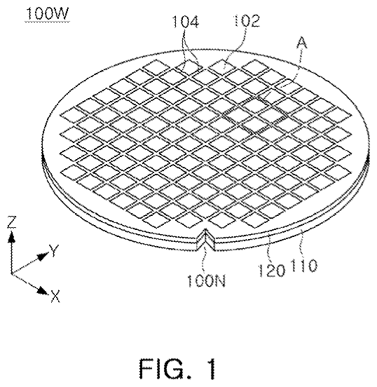

In a process of manufacturing a semiconductor chip according to one or more example embodiments, a round-shaped recess (also referred to as an anti-collision recess) is formed in a corner region of adjacent semiconductor chips prior to grinding during a cutting process, thereby preventing mutual collisions due to movement of semiconductor chips and resultant defects (e.g., cracks) during the grinding process. Such a manufacturing process will be described with reference to FIGS. 1 to 10.

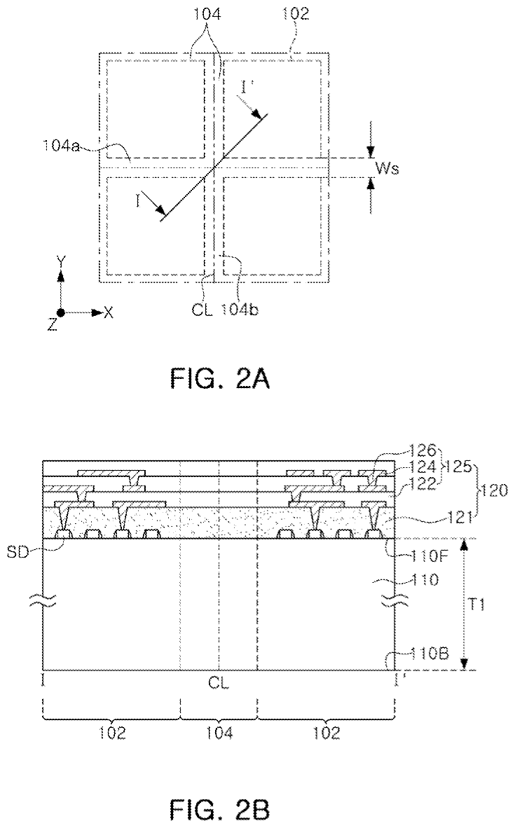

First, FIG. 1 is a perspective view illustrating a wafer structure having a device layer, FIG. 2A is an enlarged plan view of portion A of FIG. 1, and FIG. 2B is a side cross-sectional view taken along line I-I′ in FIG. 2A.

Referring to FIGS. 1 to 2B, a wafer structure 100W includes a semiconductor substrate 110 having an active surface 110F and an inactive surface 110B positioned opposite to the active surface 110F and a device layer 120 is disposed on the active surface 110F of the semiconductor substrate 110.

The wafer structure 100W may have a notch 100N used as a reference point for wafer alignment in a region of an edge thereof. The device layer 120 may include integrated circuit (IC) areas 102 and a cut area 104. Here, as shown in FIG. 2B, the IC areas 102 and the cut area 104 may extend to the semiconductor substrate 110 in a direction (e.g., Z-direction), perpendicular to the active surface 110F. The IC areas 102 and the cut area 104 may refer to different regions of the wafer structure 100W.

The semiconductor substrate 110 may be a circular wafer having a constant first thickness T1. For example, the semiconductor substrate 110 may be a silicon wafer. The disclosure is not limited thereto, and the semiconductor substrate 110 may be a semiconductor element such as germanium or a compound semiconductor wafer such as silicon carbide (SiC), gallium arsenide (GaAs), indium arsenide (InAs), and indium phosphide (InP). Alternatively, the semiconductor substrate 110 may have a silicon on insulator (SOI) structure. In some embodiments, the semiconductor substrate 110 may include a well doped with an impurity or a structure doped with an impurity, as a conductive region. Also, the semiconductor substrate 110 may have various device isolation structures such as a shallow trench isolation (STI) structure.

If the first thickness T1 of the semiconductor substrate 110 is too small, mechanical strength may be insufficient, and if the first thickness T1 is too great, a time required for subsequent grinding increases, to degrade productivity of the semiconductor chips. For example, the first thickness T1 of the semiconductor substrate 110 may be in a range of about 0.1 mm to 1 mm.

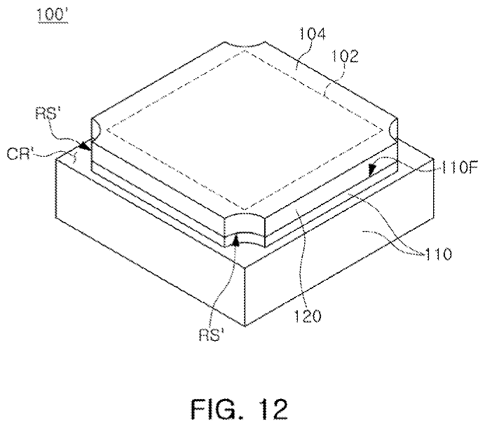

As described above, a device layer having a plurality of IC areas may be formed on the active surface 110F of the semiconductor substrate 110. The plurality of IC areas may be separated from each other together with the semiconductor substrate 110 in a subsequent process and provided as semiconductor chips (e.g., 100 and 100′ of FIGS. 11 and 12). The plurality of IC areas may include a plurality of semiconductor devices SD. The semiconductor devices SD may be classified as a memory device and a logic device.

The memory device may include a volatile memory device or a non-volatile memory device. For example, the volatile memory device may include a memory device such as dynamic random access memory (DRAM), static RAM (SRAM), thyristor RAM (TRAM), zero capacitor RAM (ZRAM), or twin transistor RAM (TTRAM). In addition, the non-volatile memory device may include memory devices, for example, a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory, or an insulator resistance change memory.

The logic element may be implemented as, for example, a microprocessor, a graphics processor, a signal processor, a network processor, an audio codec, a video codec, an application processor, or a system on chip, but is not limited thereto.

Each of the IC areas 102 may be arranged to be isolated from each other by the cut area 104. The cut area 104 may be referred to as a scribe lane. The cut area 104 may be configured as a portion 104a extending in a row direction (e.g., an X-direction) and a portion 104b extending in a column direction (e.g., a Y-direction) that cross each other as shown, e.g., in FIG. 2A. The cut area 104 may have a straight lane shape having a constant width Ws. As illustrated in FIG. 1, the IC areas 102 may be arranged in a plurality of rows and a plurality of columns with a cut area 104 interposed therebetween. Each of the IC areas 102 may be surrounded by the cut area 104 and may be disposed to be spaced apart from each other.

As described above, each of the plurality of IC areas 102 is a region in which semiconductor devices SD for memory or logic functions are formed, and the cut area 104 is a region in which such a semiconductor device is not formed. In some embodiments, a plurality of semiconductor dummy devices may be arranged in the cut area 104.

In an example embodiment, the device layer may be configured to include an interlayer insulating layer 121 disposed on the active surface 110F and covering semiconductor devices SD and an interconnection structure 125 disposed on the interlayer insulating layer 121 and connected to the semiconductor devices SD. The interconnection structure 125 may have a multilayer (e.g., three-layer) interconnection structure in which a low dielectric layer 122 and a metal interconnection 124 are alternately disposed. Also, the metal interconnection 124 of each layer may include a plurality of metal vias 126 disposed in a direction (e.g., the Z-direction), perpendicular to the active surface 110F of the semiconductor substrate 110. For example, the metal interconnection 124 and the metal via 126 may be formed of a conductive material including at least one of, for example, aluminum (Al), copper (Cu), nickel (Ni), tungsten (W), platinum (Pt), and gold (Au). In an example embodiment, the multilayer metal interconnection 124 is illustrated as three layers, but is not limited thereto. Multilayer metal interconnection 124 may include two layers or four or more layers.

The interlayer insulating layer 121 and the low dielectric layer 122 may be formed of a low-k material. The low-k material is a material having a lower dielectric constant than silicon oxide, and the use of the low-k material as the interlayer insulating layer 121 in the semiconductor device SD may be advantageous for realizing high integration and high speed of the semiconductor device SD due to improved insulation capability.

A dummy structure similar to the interconnection structure 125 may be formed in the cut area 104. For example, the dummy structure disposed in the cut area 104 may include multilayer dummy interconnections respectively corresponding to the metal interconnections 126 together with the interlayer insulating layer 121 and the low dielectric layer 122. In some embodiments, a test pattern for testing the semiconductor device SD of the IC areas 102 or a redistribution layer for connection between the test patterns may be included or an align key for aligning a mask may be included in the cut area 104. Also, in some embodiments, a material film having various functions, such as a passivation film, may be additionally formed on the device layer 120.

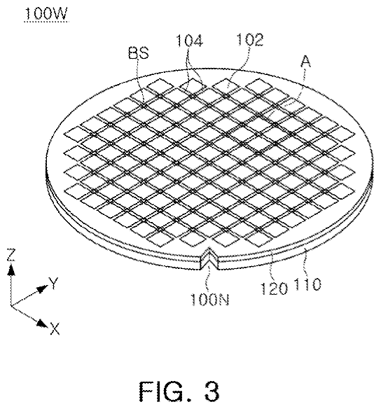

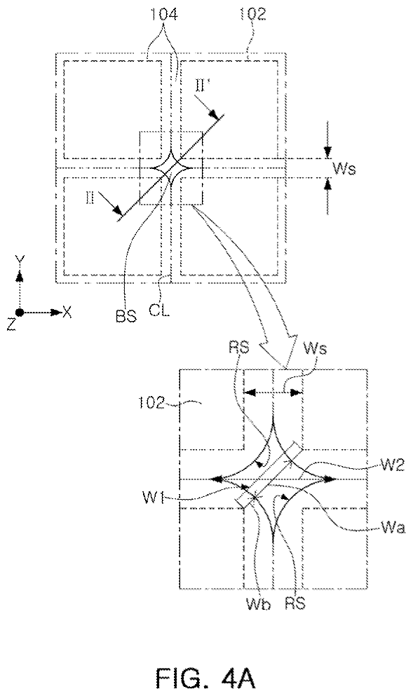

FIG. 3 is a perspective view illustrating a wafer structure according to an example embodiment, FIG. 4A is an enlarged plan view of portion A of FIG. 1, and FIG. 4B is a side cross-sectional view taken along line II-II′ of FIG. 4A.

As illustrated in FIG. 3, in the cut area 104, an anti-collision recess BS is formed in a region in which corners of the plurality of IC areas 102 are adjacent to each other. In an example embodiment, the plurality of IC areas 102 may each have a quadrangular shape (rectangular or square) and may be arranged in a plurality of rows and a plurality of columns with the cut area 104 therebetween. As illustrated in FIGS. 3 and 4A, the anti-collision recess BS may be formed in the cut area adjacent to the corners of the four IC areas 104 positioned in two adjacent rows and two adjacent columns.

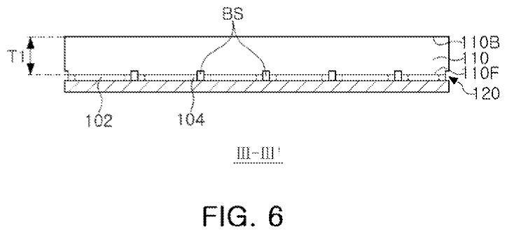

In the grinding process of the semiconductor substrate 110, semiconductor chips (not completely separated) may move by rotation and load of a grinder (refer to FIGS. 7 to 9), and in this case, collisions may occur in the corners of the adjacent semiconductor chips and cracks occurring due to such collisions may damage the IC area 102.

The anti-collision recess BS provides a buffer space that may prevent collision in a region adjacent to the four corners in the cut area 104. The anti-collision recess BS has a depth D greater than a thickness Td of the device layer 120 to sufficiently protect the IC area 102. As illustrated in FIG. 4B, the depth D of the anti-collision recess BS may extend to a partial region of the semiconductor substrate 110 beyond the device layer 120. For example, the depth D of the anti-collision recess BS may be 110% or more of the thickness Td of the device layer 120. In some embodiments, the depth D of the anti-collision recess BS may be 120% or more of the thickness Td of the device layer 120.

The anti-collision recess BS employed may have inner sidewalls respectively corresponding to four corners of the neighboring IC areas 102, as illustrated in FIG. 4A, and the inner sidewalls may have a rounded surface RS.

The anti-collision recess BS may be formed such that the cut area 104 adjacent to each corner of the four IC areas 102 partially remains. That is, when viewed in a diagonal direction of the four IC areas 102, a width Wa of the anti-collision recess BS may be less than an interval W1 between opposing corners of the IC areas 102. For example, the width Wa of the anti-collision recess BS may be 30% to 70% of the interval W1 between the opposing corners of IC areas 102.

Further, the corners of the IC areas 102 may be protected by a remaining portion of the cut area 104, and the remaining portion may have a constant thickness Wb. For sufficient protection, the shortest distance Wb between the corners of the plurality of IC areas 102 and the corresponding inner sidewall of the anti-collision recess BS may be 5 μm or more.

The anti-collision recess BS may have a structure having an inwardly rounded inner sidewall RS. As illustrated in FIG. 4A, a cross section of the anti-collision recess BS may have a deformed diamond shape. The anti-collision recess BS needs to have sufficient space to separate the IC areas 102, but the area of the cut area 104 is very narrow, so the anti-collision recess BS has a diamond shape to secure sufficient space and each inner sidewall RS advantageously has a surface curved inwardly toward the center of the anti-collision recess BS.

Referring to FIG. 4A, the anti-collision recess BS may be configured to have the width W2 in the row and/or column direction greater than the width Wa in the diagonal direction. A space for separating the IC areas 102 may be sufficiently secured while securing a residual area for protecting the IC areas 102. For example, the width W2 in the row and/or column direction (X- and/or Y-direction) may be formed to be greater by 30% or more than the width Wa in the diagonal direction, and in some embodiments, the width W2 may be formed to be greater by 50% or more. In some embodiments, the width W2 in the row and/or column direction of the anti-collision recess BS may be greater than at least the width Ws of the cut area 104.

In addition, from the viewpoint of the final semiconductor chip, when the corner of the device layer 120 has an angled structure, it is vulnerable to impacts in a subsequent process (e.g., a package manufacturing process), but since adjacent corners of the IC areas 102 are formed to have a round shape, reliability against mechanical shock in a subsequent process may be improved.

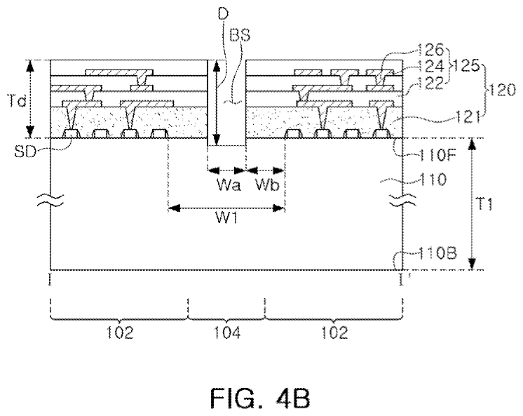

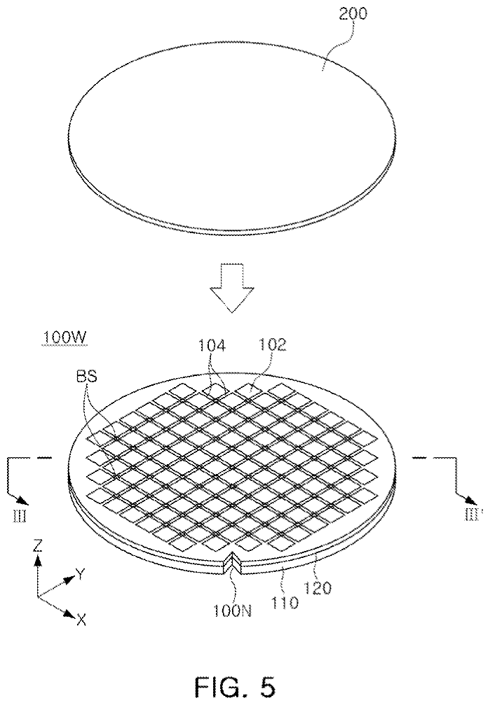

FIG. 5 is a perspective view illustrating a process of attaching a protective sheet to a wafer structure according to an example embodiment, and FIG. 6 is a side cross-sectional view of a wafer structure having a protective sheet attached thereto, taken along line III-III′ of FIG. 5.

Referring to FIGS. 5 and 6, a protective sheet 200 is attached to the device layer 120 of the wafer structure 100W.

The wafer structure 100W may be disposed such that a surface to which the protective sheet 200 is attached faces a support such as a chuck table in a subsequent cutting process (see FIG. 7). The protective sheet 200 may protect the IC areas 102, while the cutting process is performed on the wafer structure 100W. For example, the protective sheet 200 may be a polyvinylchloride (PVC)-based polymer sheet and may be attached on the device layer 120 by an acrylic resin-based adhesive, and here, the acrylic resin-based adhesive may be applied with a thickness of about 2 μm to about 10 μm. The protective sheet 200 may have a thickness of about 60 μm to about 200 μm. In some embodiments, the protective sheet 200 may be a die attach film (DAF). The protective sheet 200 may have a circular shape having substantially the same diameter as that of the wafer structure 100W.

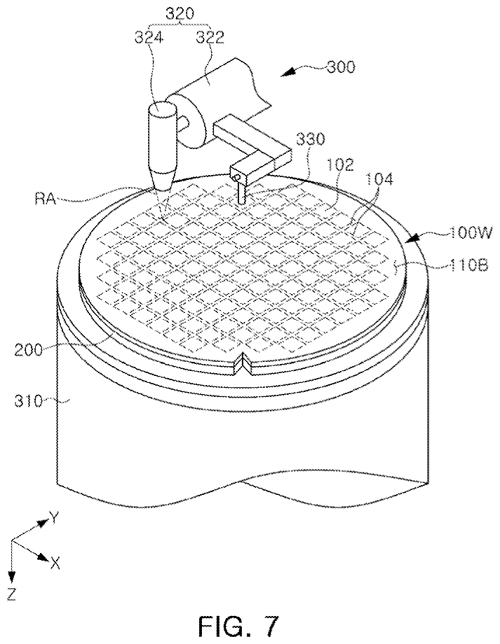

FIG. 7 is a perspective view illustrating a process of irradiating an inside of a semiconductor substrate with a laser according to an example embodiment, and FIG. 8 is a side cross-sectional view illustrating a semiconductor substrate irradiated with a laser according to an example embodiment.

Referring to FIGS. 7 and 8, after the protective sheet 200 is attached to the wafer structure 100W, a laser RA having a wavelength having a transmittance with respect to the semiconductor substrate 110 may be controlled to form a light-converging point in a specific area inside the semiconductor substrate 110.

In this manner, by irradiating the laser RA at regular intervals along a cutting line CL (see, e.g., FIG. 4A), a modified portion 150 may be formed along the cutting line CL at a constant depth inside the semiconductor substrate 110. The formation of the modified portion 150 may be performed using a laser irradiation apparatus 300.

The laser irradiation apparatus 300 may include a chuck table 310 supporting the semiconductor substrate 110, a laser irradiation unit 320 for irradiating a laser RA to the semiconductor substrate 110 disposed on the chuck table 310, and an imaging unit 330 for imaging the semiconductor substrate 110 disposed on the chuck table 310. The chuck table 310 may be configured to suction and support the semiconductor substrate 110 by vacuum pressure and move in a row direction (e.g., the X-direction) and column direction (e.g., the Y-direction).

The laser irradiation unit 320 may be configured to irradiate a pulse laser from a light concentrator 324 mounted at a front end of a substantially horizontally arranged cylindrical housing 322. Also, the chuck table 310 and the light concentrator 324 may move relative to each other at an appropriate speed, while the light concentrator 324 irradiates the semiconductor substrate 110 with a pulse laser having a transmittance.

The imaging unit 330 mounted at the other front end of the housing 322 constituting the laser irradiation unit 320 may be a general CCD imaging device for imaging using visible light. In other embodiments, the imaging unit 330 may have an infrared ray irradiation unit for irradiating the semiconductor substrate 110 with infrared rays and an optical system for capturing infrared rays irradiated by the infrared ray irradiation unit, and may include an infrared CCD imaging device for outputting an electrical signal corresponding to the infrared rays captured by the optical system.

The laser irradiation unit 320 is aligned in a laser irradiation position and subsequently irradiates a laser RA. A converging point of the laser RA, that is, the modified portion 150, may be controlled to be positioned closer to the active surface 110F than the inactive surface 110B of the semiconductor substrate 110. The laser RA emitted from the laser irradiation unit 320 may be intensively irradiated so that a portion of the semiconductor substrate 110 is heated to about 600° C. That is, the region of the semiconductor substrate 110 positioned at the converging point of the laser RA may be partially melted by the laser RA.

The modified portion 150 may be located at a distance D1 away from the inactive surface 110B of the semiconductor substrate 110, and the modified portion 150 may be positioned closer to the active surface 110F. The laser may be easily irradiated to a desired position by light amplification by stimulated emission radiation. Using the properties of the laser, the modified portion 150 may be formed at a desired location inside the semiconductor substrate 110. The modified portion 150 may act as a crack site in which cracks CR may occur due to an external physical impact.

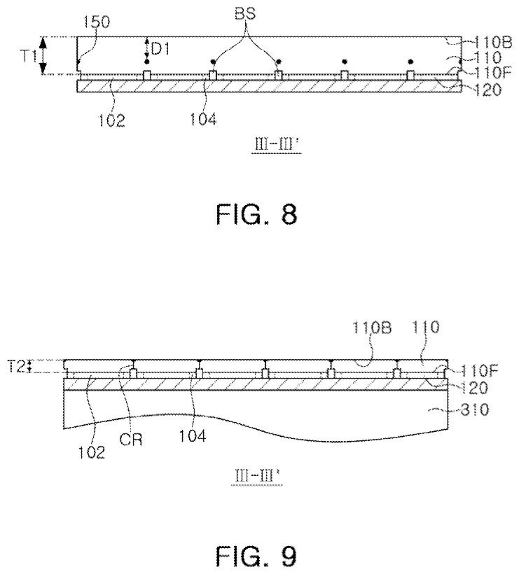

FIG. 9 is a side cross-sectional view illustrating a process of polishing a semiconductor substrate according to an example embodiment.

By polishing the inactive surface 110B of the semiconductor substrate 110 using a polishing apparatus, a thickness of the semiconductor substrate 110 may be reduced and cracks CR may propagate from the modified portion 150.

The polishing apparatus may include a chuck table supporting the semiconductor substrate 110 and a grinder polishing the semiconductor substrate 110 disposed on the chuck table. The grinder may move while rotating, and a polishing pad may be attached to a lower portion of the grinder.

The polished semiconductor substrate 110 may have a second thickness T2 less than the first thickness T1 (refer to FIG. 2B). For example, the second thickness T2 may be about 20 μm to about 100 μm. The semiconductor substrate 110 may be polished to have the desired second thickness T2 using the polishing apparatus. At the same time, in the cut area 104, the crack CR, starting from the modified portion 150, may pass through the active surface 110F of the polished semiconductor substrate 110 and propagate to the cut area 104 of the device layer 120.

According to an example embodiment, after the modified portion 150 is formed along the cut area 104 of the wafer structure 100W by irradiating the inside of the semiconductor substrate 110 with a laser, the inactive surface 110B of the substrate 110 may be polished. The polishing process may be a grinding process in a state in which physical pressure is applied to the semiconductor substrate 110. When the polishing process is performed in a state in which physical pressure is applied to the semiconductor substrate 110, the polished semiconductor substrate 110 may be brittle-fractured. Brittle fracture refers to fracture without permanent deformation when a force greater than an elastic limit is applied to an object. Accordingly, the semiconductor substrate 110 becoming thinner, while polishing the inactive surface 110B of the semiconductor substrate 110, may become brittle and fractured by the cracks CR propagated from the modified portion 150.

As the crack CR propagating from the modified portion 150 is formed along the cut area 104 that isolates the IC areas 102, the IC areas 120 may be separated into the semiconductor chips 100 by brittle fracture of the semiconductor substrate 110.

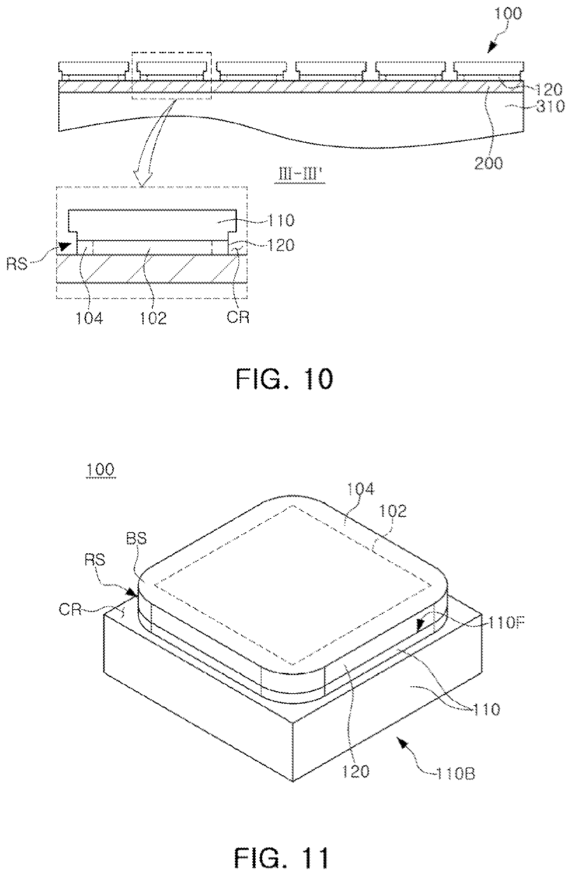

The separated semiconductor chips 100 may be fixed without being separated from the original positions by the protective sheet 200 as shown, e.g., in FIG. 10.

As described above, in the grinding process of the semiconductor substrate 110, the semiconductor chip portions may move even if they are not completely separated by the rotation and load of the grinder, and in this movement process, adjacent semiconductor chips collide with each other. In particular, collisions occurring in corner regions of semiconductor chip portions may easily cause cracks, and due to the cracks, the IC area 102 may be damaged to cause fatal defects. The anti-collision recess BS formed in the previous process provides a buffer space that may prevent collisions in the region adjacent to the four corners in the cut area 104, thereby preventing the collision of adjacent corners and effectively suppressing an occurrence of defects.

Since the anti-collision recess BS employed in the present embodiment has a structure having a convex rounded inner sidewall RS as described above, it is possible to secure sufficient space, even in the narrow cut area 104. In addition, from the viewpoint of the final semiconductor chip, the adjacent corners of the IC areas 102 may have a round shape, thereby improving reliability against mechanical shocks in a subsequent process.

In some embodiments, the inactive surface 110B of the semiconductor substrate 110 may be polished to completely remove the modified portion 150. Referring to a cut surface of the semiconductor chip 100 in which the modified portion 150 is completely removed and separated, the cut surface may be relatively smoother than the cut surface mechanically cut using a sawing blade. In addition, since all crack sites in the modified portion 150 may be removed by completely removing the modified portion 150 in the polishing process, no more cracks CR may occur.

In addition, a cut width of the semiconductor substrate 110 may be relatively reduced using a laser. Therefore, a width of the cut area 104 may be relatively reduced, as compared to a mechanical cutting process using a sawing blade, so that more IC areas 102 may be formed on the semiconductor substrate 110.

FIG. 10 is a side cross-sectional view illustrating a process of cutting a semiconductor substrate into semiconductor chips according to an example embodiment.

The wafer structure 100W may be separated into respective semiconductor chips 100 by a cutting process. Specifically, in the wafer structure 100W, the IC areas 102 may be separated into respective semiconductor chips 100 by the crack CR of the cut area 104. The separated semiconductor chips 100 may be fixed without being separated from their original positions by the protective sheet 200. By extending the protective sheet 200 to which the individualized semiconductor chips 100 are attached in the X-Y direction, a space between the semiconductor chips 100 may be secured and the semiconductor chips 100 may be easily picked up.

FIGS. 11 and 12 are perspective views illustrating a semiconductor chip according to various example embodiments.

Referring to FIG. 11, a semiconductor chip 100 according to an example embodiment may include a semiconductor substrate 110 having a first surface 110F and a second surface 110B positioned opposite to each other and having a rectangular parallelepiped structure and a device layer 120 disposed on the first surface 110F. Here, the first surface 110F may be referred to as an active surface, and the second surface 110B may be referred to as an inactive surface.

The device layer 120 may have an IC area 102 including semiconductor devices and interconnection layers and a peripheral protective area 104 surrounding the IC area 102. The peripheral protective area 104 may be a portion of a cut area and may be an area remaining after the cutting process. The peripheral protective area 104 may have recessed portions CR so that regions adjacent to four corners of the first surface 110F of the semiconductor substrate 110 may be exposed. Each of the recessed portions CR of the peripheral protective area 104 may have a rounded side surface RS. In the present embodiment, the rounded side surface RS may be a convexly rounded side surface with respect to a center of the semiconductor chip 100.

As illustrated in FIG. 11, since the corner of the device layer 120 has a round shape, reliability against undesired mechanical impact in a subsequent packaging process may be improved. Each of the recessed portions CR may extend to a partial region of the semiconductor substrate 110 to a depth greater than a depth of the device layer 120. A minimal thickness (or width) of the peripheral protective area 104 positioned in the recessed portions CR may be equal to or smaller than the thickness (or width) of other portions of the peripheral protective area 104.

Referring to FIG. 12, a semiconductor chip 100′ according to an example embodiment has a structure similar to that of the semiconductor chip 100 illustrated in FIG. 11, except that the rounded side surface RS′ is concave with respect to the center of the semiconductor chip 100′. Accordingly, the description of the semiconductor chip 100 illustrated in FIG. 11 may be combined with the description of the semiconductor chip 100′ according to an embodiment unless otherwise specified.

Similar to the previous embodiment, the peripheral protective area 104 may have recessed portions CR′ so that regions adjacent to four corners of the first surface 110F of the semiconductor substrate 110 are exposed. The recessed portions CR′ of the peripheral protective area 104 may have a concavely rounded side surface RS′ with respect to the center of the semiconductor chip 100′. The concavely rounded side surface RS′ may be obtained by forming an anti-collision recess having a circular or circular-like or an elliptical plane in the process illustrated in FIGS. 3 and 4A.

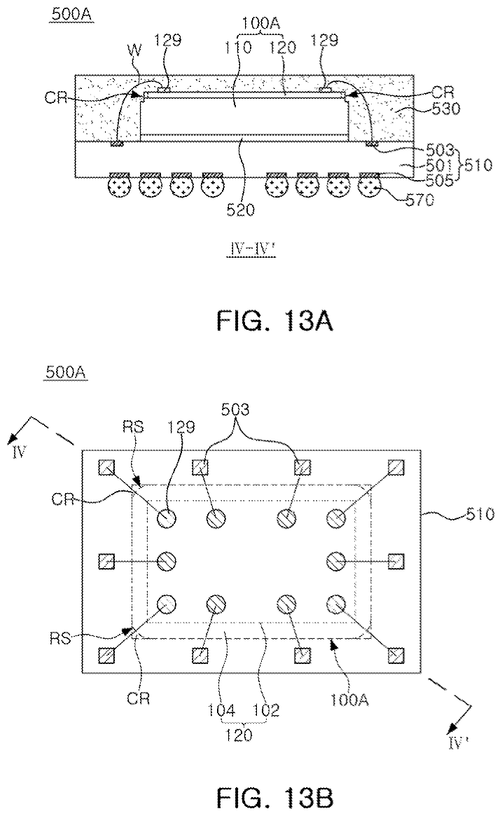

FIGS. 13A and 13B are a side cross-sectional view and a plan view illustrating a semiconductor package including a semiconductor chip according to an example embodiment. FIG. 13A is a cross-sectional view of the semiconductor package of FIG. 13B, taken along line III-III′.

Referring to FIGS. 13A and 13B, a semiconductor package 500A according to an example embodiment includes a package substrate 510, a semiconductor chip 100A disposed on the package substrate 510, and a molding member 530 surrounding the semiconductor chip 100A on the package substrate 510.

The package substrate 510 may include a body portion 501, upper pads 503 on an upper surface of the body portion 501, and lower pads 505 on a lower surface of the body portion 501. The package substrate 510 may be a printed circuit board (PCB), a semiconductor substrate, a ceramic substrate, or a glass substrate. In some embodiments, the package substrate 510 may be an interposer substrate. Meanwhile, the package substrate 510 may include an interconnection disposed in the body portion 501 and connecting the upper pads 503 and the lower pads 505.

The semiconductor chip 100A may be disposed on the package substrate 510 using an adhesive layer 520, and a connection pad 129 of the semiconductor chip 100A may be connected to the upper pad by a wire W. The semiconductor chip 100A may be electrically connected to external connection terminals 570 disposed on the lower pads 505 of the package substrate 510 through the upper pads 503, the interconnection, and lower pads 505. The semiconductor package 500A may be mounted, while being electrically connected to an external substrate such as a module substrate or a system board of an electronic product through external connection terminals 570.

In an example embodiment, the semiconductor chip 100A may include a semiconductor substrate 110 and a device layer 120 disposed on the active surface 110F of the semiconductor substrate 110. In the semiconductor chip 100A, a passivation layer may be formed on the device layer 120 to protect the device layer 120 from external impact or moisture.

The device layer 120 includes an IC area 102 and a peripheral protective area 104 surrounding the IC area 102. As described above, the peripheral protective area 104 may refer to a portion of a cut area described above in the previous process and may refer to a region remaining after the cutting process.

As illustrated in FIG. 13B, each of the recessed portions CR may be provided at four corners of the semiconductor chip 100A in the peripheral protective areas 104. Each of the recessed portions CR has a rounded side surface RS. The rounded side surface RS is illustrated as a convexly rounded side surface with respect to the center of the semiconductor chip 100A. In another example embodiment, the recessed portion CR may be a concavely rounded side surface (e.g., see FIG. 12). The recessed portion CR may extend to a partial region of the semiconductor substrate 110 to a depth greater than a depth of the device layer 120. For example, a depth of the recessed portion CR may be 110% or more of a thickness of the device layer 120. In some embodiments, the thickness of the semiconductor chip 100A may be in the range of 50 μm to 150 μm, and the depth of the recessed portion CR may be in the range of 15 μm to 40 μm.

The molding member 530 may surround the semiconductor chip 100A and may serve to protect the semiconductor chip 100A from an external environment. The molding member 530 may be formed by injecting an appropriate amount of molding resin onto the package substrate 510 by an injection process, and may form an exterior of the semiconductor package 500A through a curing process. In some embodiments, the exterior of the semiconductor package 500A may be formed by applying pressure to the molding resin in a pressing process such as pressing. Here, process conditions such as a delay time between injection of the molding resin and pressing, the amount of the injected molding resin, and pressing temperature/pressure may be set in consideration of physical properties such as viscosity of the molding resin, etc. For example, the molding resin may include an epoxy-group molding resin or a polyimide-group molding resin. In some embodiments, the molding member 530 may be formed of an epoxy molding compound (EMC).

Side and upper surfaces of the molding member 530 may have a right angle shape. Each semiconductor package 500A may be manufactured by cutting the package substrate 510 along a cutting line. Although not illustrated, a marking pattern including information of the semiconductor chip 100A, for example, a barcode, number, character, symbol, etc., may be formed on a portion of the side surface of the semiconductor package 500A.

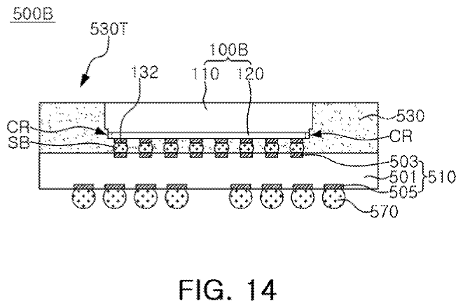

FIG. 14 is a side cross-sectional view illustrating a semiconductor package including a semiconductor chip according to an example embodiment.

Referring to FIG. 14, a semiconductor package 500B according to an example embodiment has a structure in which a semiconductor device 100B is connected to the package substrate 510 by a flip-chip bonding method, and thus, the semiconductor package 500B may be understood as having a structure similar to that of the semiconductor package 500A illustrated in FIGS. 13A and 13B, except that the recessed portion RC is disposed to face an upper surface of the package substrate 510. Therefore, the description of the semiconductor package 500A illustrated in FIGS. 13A and 13B may be combined with the description of the semiconductor package 500A according to an embodiment unless otherwise specified.

The semiconductor chip 100B may be mounted on the package substrate 510 so that the active surface faces an upper surface of the package substrate 510. Connection pads 132 of the semiconductor chip 100B may be connected to the upper pads 503 by conductive bumps SB.

Each of the four corners of the peripheral protective area 104 of the semiconductor chip 100B may have a recessed portion CR, and the recessed portions CR may each have a rounded side surface RS. The recessed portion CR may be positioned to face the package substrate 510. The recessed portion CR may extend to a partial region of the semiconductor substrate 110 to a depth greater than a depth of the device layer 120.

The semiconductor chip 100B may be disposed such that an inactive surface of the semiconductor substrate 110 faces upwardly. As illustrated in FIG. 14, the inactive surface of the semiconductor substrate 110 may be exposed through an upper surface 530T of the molding member 530. For example, the upper surface of the semiconductor chip 100B may be substantially coplanar with the upper surface 530T of the molding member 530.

As set forth above, in the disclosure, by forming a round-shaped recess in advance in the corner region of the semiconductor chips in a wafer to be cut, mutual collision due to movement of the semiconductor chips during a grinding process included in a cutting process using a laser and resultant defects (e.g., cracks) of the semiconductor chips may be effectively prevented.

While example embodiments have been illustrated and described above, it will be apparent to those skilled in the art that modifications and variations could be made without departing from the scope of the disclosure as defined by the appended claims.

1. A method of manufacturing a semiconductor chip, the method comprising:
preparing a semiconductor substrate having an active surface on which a device layer is provided and an inactive surface opposite to the active surface, the device layer having a plurality of integrated circuit (IC) areas and a cut area provided between adjacent IC areas of the plurality of IC areas;
forming anti-collision recesses in regions of the cut area that are adjacent to corners of the plurality of IC areas, each of the anti-collision recesses having rounded internal sidewalls, each of the rounded internal sidewalls corresponding to a respective corner of the adjacent corners;
forming a modified portion in the semiconductor substrate by irradiating a cut line of the cut area with a laser;
polishing the inactive surface of the semiconductor substrate; and
separating the plurality of IC areas from each other along cracks that propagate from the modified portion in a vertical direction of the semiconductor substrate, to form a plurality of semiconductor chips.

2. The method of claim 1, wherein each of the plurality of IC areas has a quadrangular shape,
wherein the plurality of IC areas are arranged in a plurality of rows and a plurality of columns with the cut area therebetween, and
wherein each of the regions adjacent to the corners is adjacent to respective corners of four IC areas positioned in two adjacent rows and two adjacent columns.

3. The method of claim 2, wherein each of the anti-collision recesses has a width ranging from about 30% to about 70% of an interval between IC areas of the four IC areas that are arranged in a diagonal direction.

4. The method of claim 2, wherein a shortest interval between each of the corners of the plurality of IC areas and a corresponding rounded internal sidewall is 5 μm or greater.

5. The method of claim 1, wherein each of the anti-collision recesses has a depth that is greater than a thickness of the device layer.

6. The method of claim 5, wherein the depth of each of the anti-collision recesses is at least 110% of the thickness of the device layer.

7. The method of claim 1, wherein the polishing comprises:
bonding a protective sheet to the active surface of the semiconductor substrate; and
disposing the active surface to which the protective sheet is bonded, on a support for a polishing device.

8. The method of claim 1, wherein each of the rounded internal sidewalls of the anti-collision recesses have an inwardly curved structure.

9. The method of claim 1, wherein each of the anti-collision recesses has a circular or oval flat cross-section when viewed in a direction perpendicular to the active surface of the semiconductor substrate.

10. A method of manufacturing a semiconductor chip, the method comprising:
preparing a semiconductor substrate having an active surface on which a device layer is provided and an inactive surface positioned opposite to the active surface, the device layer having a plurality of integrated circuit (IC) areas arranged in a plurality of rows and a plurality of columns and a cut area provided between adjacent IC areas of the plurality of IC areas, each of the plurality of IC areas having a quadrangular shape;
forming anti-collision recesses in regions of the cut area that are adjacent to four corners of the plurality of IC areas, each of the anti-collision recesses having inwardly curved and rounded internal sidewalls, each of the internal sidewalls corresponding to a respective corner of the four corners;
forming a modified portion in the semiconductor substrate by irradiating a cut line of the cut area with a laser;
polishing the inactive surface of the semiconductor substrate in a state in which the active surface is disposed in a support; and
separating the plurality of IC areas from each other along cracks that propagate from the modified portion in a vertical direction of the semiconductor substrate, to form a plurality of semiconductor chips.

11. The method of claim 10, wherein each of the anti-collision recesses has a depth greater than a thickness of the device layer and extends into the semiconductor substrate.

12. The method of claim 10, wherein a width of each of the anti-collision recesses in a row or column direction is greater than a width thereof in a diagonal direction of the four corners by at least 30%.

13. The method of claim 10, wherein each of the plurality of semiconductor chips has four corners, and
wherein an upper region of each of the four corners of each of the plurality of semiconductor chips has a rounded portion.

14. The method of claim 12, wherein each of the plurality of semiconductor chips has an IC area and a peripheral protective area surrounding the IC area, and
wherein the peripheral protective area is a residual area of the cut area.

15. The method of claim 14, wherein a shortest interval from each of the four corners of the plurality of IC areas to a corresponding internal sidewall is equal to or smaller than a thickness of the peripheral protective area positioned at each of the four corners of the plurality of IC areas.

16-20. (canceled)
